(19) United States
(12) Patent Application Publication
(10) Pub. No.: US 2026/0206346 A1
(43) Pub. Date: Jul. 16, 2026

(54) IMAGE SENSOR AND METHOD OF MANUFACTURING THE SAME

(71) Applicant: Taiwan Semiconductor Manufacturing Company, Ltd., Hsinchu (TW)

(72) Inventors: Keng-Yu Chou, Kaohsiung City (TW); Cheng-Yu Huang, Hsinchu (TW); Chun-Hao Chuang, Hsinchu City (TW); Wen-Hau Wu, New Taipei City (TW); Wei-Chieh Chiang, Yuanlin Township (TW); Chih-Kung Chang, Zhudong Township (TW)

(21) Appl. No.: 19/018,276

(22) Filed: Jan. 13, 2025

(51) Int. Cl. H10F 39/00; H04N 25/62

(52) U.S. Cl. CPC H10F 39/8063; H10F 39/024; H10F 39/8053; H04N 25/62

(57) ABSTRACT

Some embodiments relate to an integrated device, including: a substrate having a first refractive index, a first side, a second side, and a first and second region extending between the first side and the second side; a lower insulative grid structure within the substrate, the lower insulative grid structure having a first plurality of insulative segments arranged in a grid pattern and having a second refractive index, and extending between the first region of the substrate and the second region of the substrate; an upper insulative grid structure overlying the lower grid structure and comprising a second plurality of insulative segments that have outer sidewalls that are substantially aligned with outer sidewalls of the first plurality of insulative segments, the second plurality of insulative segments having a third refractive index that is greater than the second refractive index and lower than the first refractive index.

### BACKGROUND

Integrated circuits (ICs) with image sensors are used in a wide range of modern-day electronic devices such as, for example, cameras, cellphones, and the like. Image sensors use an array of photodetectors to detect an image and transfer signals derived from that image to an image processing circuit. Some image sensors use multiple photodetectors for the purpose of phase detection auto focus (PDAF). PDAF uses differences in the light absorbed by adjacent photodetectors to rapidly adjust the focus of the camera to achieve a sharper image.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion.

FIGS. 1A and 1B illustrate a cross-sectional view and a top down view of some embodiments of an image sensor with a dual material fill to reduce cross-talk.

FIGS. 2A and 2B illustrate a cross-sectional view and a top down view of some embodiments of an image sensor with a dual material fill to reduce cross-talk, where an overlying insulative layer extends into a portion of the second plurality of segments in the upper insulative grid structure.

FIGS. 3A and 3B illustrate a cross-sectional view and a top down view of some embodiments of an image sensor with a dual material fill to reduce cross-talk, where an overlying insulative layer separates portions of the DTI segments comprising a material with a higher refractive index than the overlying insulative layer.

FIGS. 4A, 4B, and 4C illustrate cross-sectional views of an image sensor comprising floating diffusion regions shared between multiple transfer transistors.

FIG. 5 illustrates a top down view of an image sensor with two photodetector regions beneath one microlens.

FIGS. 6-14 illustrate a series of cross-sectional views of some embodiments of a method of forming an image sensor with a dual material fill to reduce cross-talk.

FIGS. 15-20 illustrate a series of cross-sectional views of some embodiments of a method of forming a DTI structure with a dual material fill where DTI segments extending between first and second photodetectors are separated by a first insulative segment that is thinner than a second insulative segment to one side of the first and second photodetector regions.

FIGS. 21-23 illustrate a series of cross-sectional views of some embodiments of a method of forming a DTI structure with a dual material fill where an overlying insulative layer separates portions of the DTI segments comprising a material with a higher refractive index than the overlying insulative layer.

FIG. 24 illustrates a flowchart of some embodiments of a method of forming an image sensor with a dual material fill to reduce cross-talk.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

An image sensor comprises a pixel array with a plurality of photodetectors and a plurality of pixel circuits coupled to the photodetectors. The plurality of photodetectors is organized in a plurality of rows and columns, forming a photodetector array. A plurality of microlenses are arranged over the photodetector array. Image sensors utilizing a dual photodiode (DPD) or quad photodiode (QPD) design for integrated phase detection auto focus (PDAF) respectively have two or four photodetectors beneath the microlenses. Image sensors with this structure may use PDAF to aid in focusing the camera lens over the image sensor, achieving a faster focusing method than contrast phase detection techniques.

In some embodiments, when two or four photodetectors are beneath one microlens, light directed to the microlens is focused onto the deep trench isolation (DTI) structure separating the photodetectors. The difference in refractive indices between the material of the DTI structure (e.g., silicon dioxide with a refractive index of 1.48 or the like) and the material of the substrate (e.g., silicon with a refractive index of 4.0 or the like) results in light entering the image sensor through the DTI structure to be scattered as it enters the substrate. The scattering of light from the difference in refractive indices results in an increased amount of cross-talk between adjacent photodetectors as photons are directed in a direction close to normal to the sidewalls of the DTI structure.

One method of resolving this issue removes a portion of the DTI structure that the microlens is centered on. While this method reduces the amount of scattering, removing the DTI structure results in a greater number of other methods of isolating the photodetectors (e.g., ion implantation, additional high-k films, plasma doping, or the like) being used to maintain approximately the same level of isolation, reducing the full well capacity of the device. Further, in embodiments with a lower substrate thickness (e.g., a thickness between 3 and 4 micrometers), the more direct angle of the light as it passes through the portion of the substrate centered beneath the microlens may reduce the amount of red light absorbed by the photodetectors, reducing the quantum efficiency of photodetectors under red color filters. Therefore, a method of reducing the scattering of photons directed towards the DTI structure while not removing a central portion of the DTI structure is desirable.

The present disclosure provides for a DTI structure comprising a first plurality of insulative segments and a second plurality of insulative segments overlying the first plurality of insulative segments. The substrate surrounding the first plurality of insulative segments has a first refractive index (e.g., the substrate comprises silicon or the like and has a first refractive index of about 4.0), the first plurality of insulative segments have a second refractive index (e.g., as silicon dioxide or the like, with a second refractive index of about 1.48, and the second plurality of insulative segments have a third refractive index (e.g., a refractive index greater than 2). The first plurality of insulative segments are arranged in a grid pattern surrounding photodetector regions of the substrate. The second plurality of insulative segments are arranged in a grid pattern that is aligned with the grid pattern of the first plurality of insulative segments.

When the microlens directs the light towards the second plurality of insulative segments and it passes through to the substrate, the increased refractive index of the second plurality of insulative segments results in a reduction in the scattering of the photons entering the substrate. The reduction in the degree of scattering reduces the amount of crosstalk between the photodetectors while maintaining the isolation provided by the first insulative material in the DTI structure. Further, as the portion of the DTI structure that the micro lens is focus on has not been removed, there is not drop in quantum efficiency in red pixels, reduction in full well capacity, or added manufacturing steps for further isolating the photodetectors.

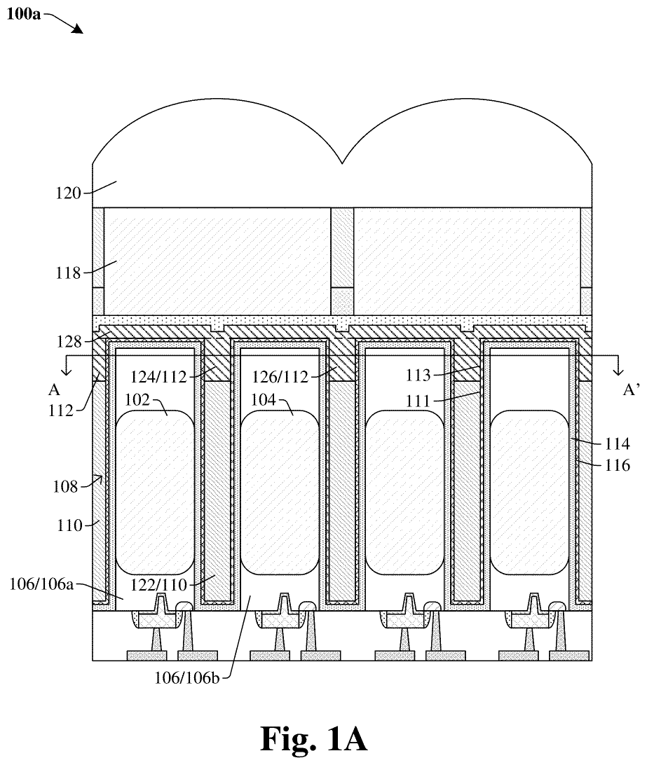

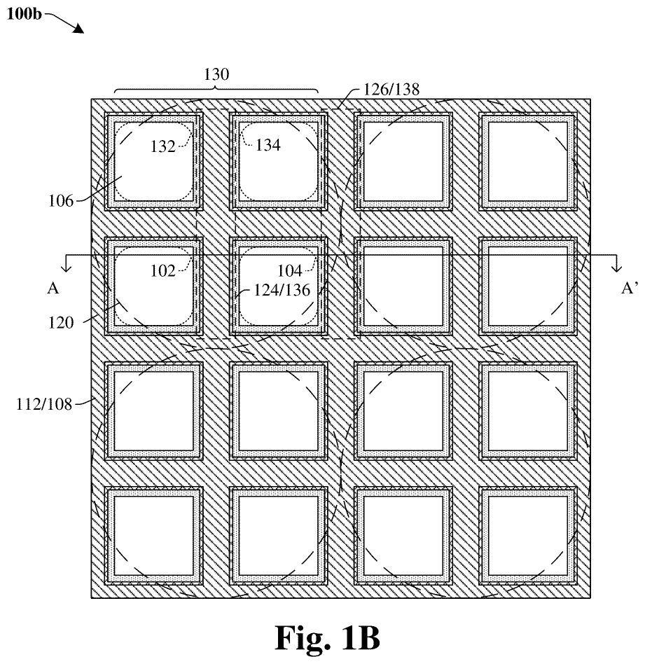

FIGS. 1A and 1B illustrate a cross-sectional view 100a and a top down view 100b of some embodiments of an image sensor with a dual material fill to reduce cross-talk. The cross-sectional view 100a of FIG. 1A is taken along line A-A′ of the top down view 100b of FIG. 1B.

A first photodetector 102 and a second photodetector 104 are within a first substrate region 106a and a second substrate region 106b of a substrate 106. A deep trench isolation (DTI) structure 108 spaces the first photodetector 102 from the second photodetector 104. The DTI structure 108 comprises a lower insulative grid structure 110 and an upper insulative grid structure 112. The lower insulative grid structure 110 comprises a first plurality of insulative segments arranged in a grid pattern. The upper insulative grid structure 112 comprises a second plurality of insulative segments with outer sidewalls 113 that are substantially aligned with outer sidewalls 111 of the first plurality of insulative segments. In some embodiments, an antireflective coating 114 and an etch stop layer 116 surround the lower insulative grid structure 110 and the upper insulative grid structure 112.

The substrate 106 comprises a semiconductor material, such as silicon, germanium, silicon germanium, sapphire, or the like. The substrate 106 has a first refractive index. In some embodiments, the lower insulative grid structure 110 is an insulative material, such as silicon dioxide (SiO₂) or the like, and has a second refractive index that is less than the first refractive index. In some embodiments, the upper insulative grid structure 112 is or comprises an insulative material (e.g., silicon nitride (Si₃N₄), hafnium oxide (HfO₂), tantalum oxide (HfO₂), titanium oxide (TiO₂), or the like) with a third refractive index that is greater than the second refractive index and lower than the first refractive index. In some embodiments, the third refractive index is greater than 2 (e.g., silicon nitride (Si₃N₄) with a refractive index of 2.046, tantalum oxide (Ta₂O₅) with a refractive index of 2.131, titanium oxide (TiO₂) with a refractive index of 2.614, or the like).

A color filter 118 extends over the first photodetector 102 and the second photodetector 104. Further, a first microlens 120 extends over the first photodetector 102 and the second photodetector 104. The first microlens 120 is configured to direct light from a first side of a focal lens towards the first photodetector 102 and light from a second side of the focal lens towards the second photodetector 104. As the light is from different parts of the focal lens, differences in the signal received are can be processed to bring the image into focus using phase detection auto focus (PDAF).

The upper insulative grid structure 112 having a refractive index greater than 2 results in light directed through the upper insulative grid structure 112 scattering as it enters the substrate 106 less than light directed through a material with a lower refractive index and into the substrate 106. Further, the DTI structure 108 extends across the focal point of the first microlens 120 (e.g., portions of the DTI structure 108 at the focal point of the first microlens 120 are not removed to reduce scattering), resulting in additional isolation techniques being omitted from the final design, thereby maintaining a higher full well capacity than image sensors using implantation and plasma doping techniques to isolate the first photodetector 102 from the second photodetector 104. Removing the DTI structure 108 at the focal point would also increase the array edge channel mismatch, as the DTI structure 108 reduces the mismatch in intensity of signals for photodetectors near the edge of the photodetector array by blocking light that is introduced to the first microlens 120 at oblique angles from entering the incorrect photodetector. Embodiments utilizing an upper insulative grid structure 112 having a refractive index greater than 2 result in a reduction in cross-talk without the known issues associated with maintaining an opening in the DTI structure 108 at the focal point of the first microlens 120. Therefore, the disclosed embodiments have improved performance over other designs without the photodetector array experiencing additional optical side effects resulting from other solutions.

In some embodiments, the first plurality of insulative segments making up the lower insulative grid structure 110 comprises a first insulative segment 122 extending between the first photodetector 102 and the second photodetector 104, and second plurality of insulative segments making up the upper insulative grid structure 112 comprise a second insulative segment 124 extending directly over and covering a top surface of the first insulative segment. In some embodiments, the upper insulative grid structure 112 further comprises a third insulative segment 126 consisting of the third material extending to one side of the first photodetector 102 and the second photodetector 104. In further embodiments, an upper insulative layer 128 that is or comprises a same material as the upper insulative grid structure 112 extends over a first surface of the substrate 106 and is mechanically coupled to the second insulative segment 124 and the third insulative segment 126.

As shown in the top down view 100b of FIG. 1B, in some embodiments, the upper insulative grid structure 112 separates the substrate 106 directly beneath the first microlens 120 (shown in phantom) into four substrate regions 130, the four substrate regions 130 having the first photodetector 102 (shown in phantom), the second photodetector 104 (shown in phantom), a third photodetector 132 (shown in phantom), and a fourth photodetector 134 (shown in phantom). Other microlenses are also positioned over sets of four substrate regions within the substrate 106. Insulative segments of the DTI structure 108 that extend between photodetectors beneath the same color filters (e.g., the first insulative segment (see 122 of FIG. 1A) and the second insulative segment 124) are also referred to as internal isolating segments 136. Insulative segments of the DTI structure 108 that extend between photodetectors beneath different color filters (e.g., the third insulative segment 126) are also referred to as external isolating segments 138.

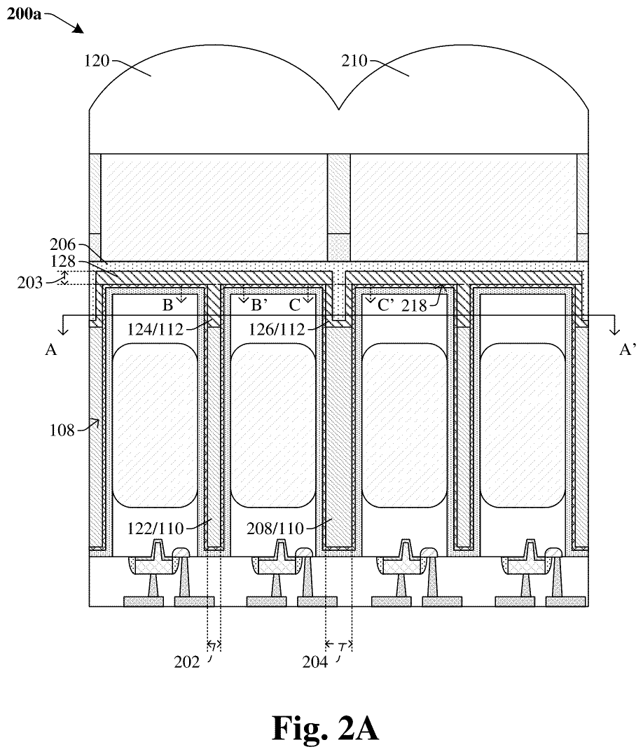

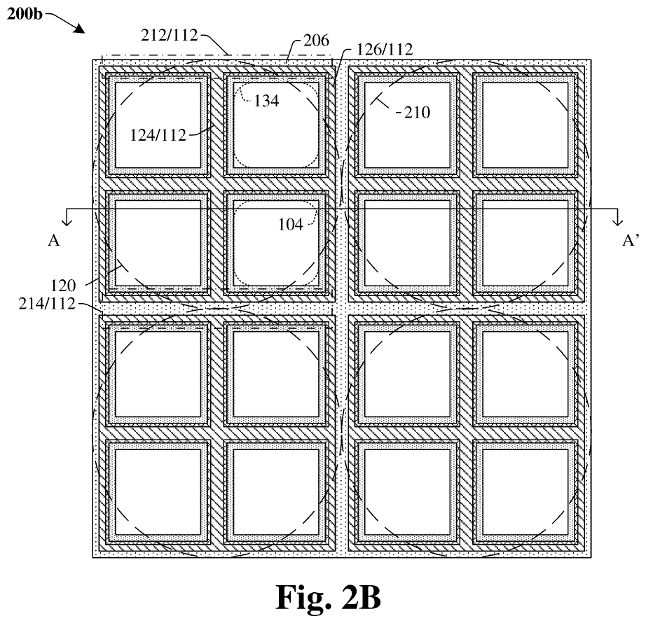

FIGS. 2A and 2B illustrate a cross-sectional view 200a and a top down view 200b of some embodiments of an image sensor with a dual material fill to reduce cross-talk, where an overlying insulative layer extends into a portion of the second plurality of segments in the upper insulative grid structure. The cross-sectional view 200a of FIG. 2A is taken along line A-A′ of the top down view 200b of FIG. 2B. FIGS. 2A and 2B are described concurrently.

In some embodiments, the first insulative segment 122 and the second insulative segment 124 have a first thickness 202. In some embodiments, the first thickness 202 is less than half of a height 203 of the upper insulative layer 128. In further embodiments, the first thickness is less than 1 micrometer. In some embodiments, the third insulative segment has a second thickness 204 that is greater than the first thickness 202. Further, a portion of an overlying insulative layer 206 extends into the third insulative segment 126 without extending into the second insulative segment 124. The portion of the overlying insulative layer 206 extending into the third insulative segment 126 is also referred to as an insulative core.

The second thickness 204 of the third insulative segment 126 and a fourth insulative segment 208 directly beneath the third insulative segment 126 results in a higher degree of isolation between photodetectors beneath the first microlens 120 and photodetectors beneath a second microlens 210. Further, the thicker insulative segments of the upper insulative grid structure 112 do not use the high-n material of the upper insulative grid structure 112 to reduce scattering, as the microlenses direct incident light towards the thinner insulative segments (e.g., the first insulative segment 122 and the second insulative segment 124), such that the overlying insulative layer 206 extending into the third insulative segment 126 does not interfere with the operation of the device. In this embodiment, the high-n material of the upper insulative grid structure 112 reduces crosstalk within the photodetector array while maintaining flexibility in the thickness of the insulative segments extending between photodetectors beneath different microlenses. The flexibility of thickness results in increased performance as the thickness can be optimized for isolation, device footprint, and full-well capacity (e.g., by increasing space within the substrate regions available for use by the photodetectors).

In some embodiments, insulative segments extending between microlenses (e.g., the third insulative segment extending between the first microlens 120 and a second microlens 210 (see FIG. 2B)) have a portion of the overlying insulative layer 206 extending into them. Further, insulative segments of the upper insulative grid structure 112 confined beneath one color filter (e.g., the internal isolating segments 136 such as the second insulative segment 124 confined beneath the first microlens 120 by a fifth insulative segment 212 and a sixth insulative segment 214) do not have a portion of the overlying insulative layer 206 extending into them. That is, a continuous line segment (extending from B-B′ of FIG. 2A) may be drawn between the lower surface 218 of the upper insulative layer 128 on a first side of the second insulative segment 124 and the lower surface 218 of the upper insulative layer 128 on a second side of the second insulative segment 124 opposite the first side without extending through the overlying insulative layer 206. Further, a continuous line segment (extending from C-C′ of FIG. 2A) drawn between lower surface 218 of the upper insulative layer 128 on a first side of the third insulative segment 126 and the lower surface 218 of the upper insulative layer 128 on a second side of the third insulative segment 126 opposite the first side extends through the overlying insulative layer 206.

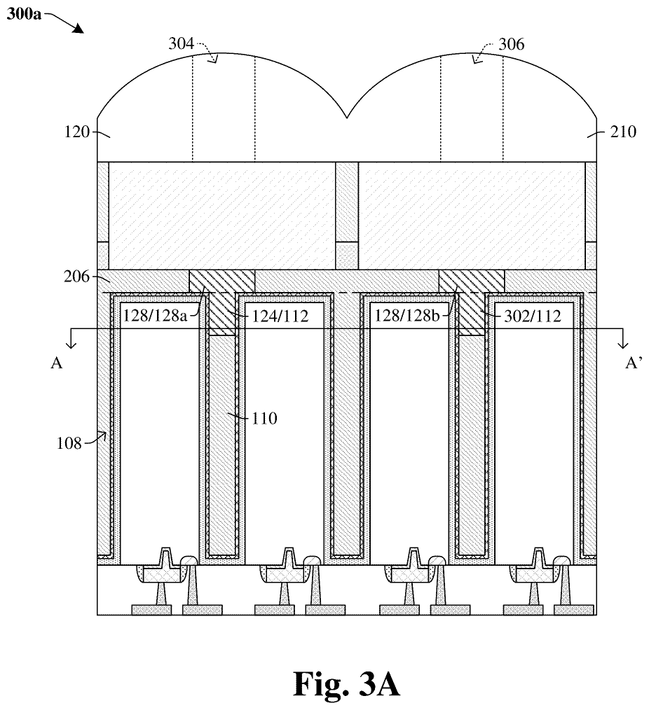

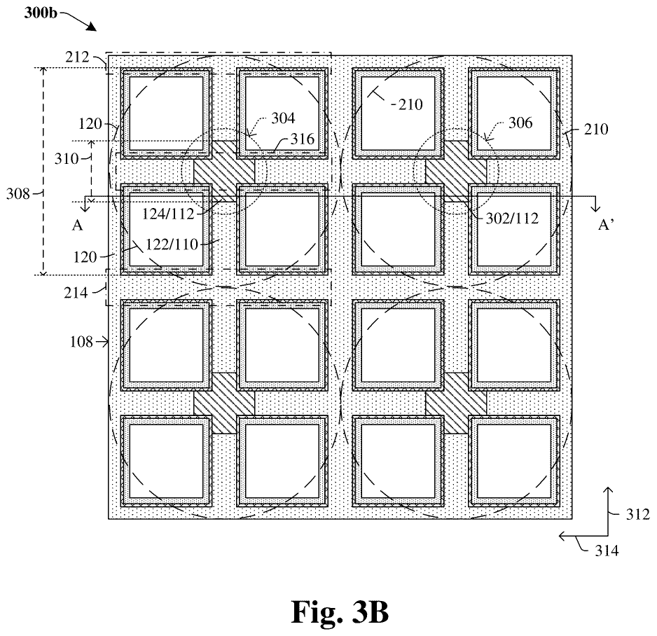

FIGS. 3A and 3B illustrate a cross-sectional view 300a and a top down view 300b of some embodiments of an image sensor with a dual material fill to reduce cross-talk, where an overlying insulative layer separates portions of the DTI segments comprising a material with a higher refractive index than the overlying insulative layer. The cross-sectional view 300a of FIG. 3A is taken along line A-A′ of the top down view 300b of FIG. 3B. FIGS. 3A and 3B are described concurrently.

In some embodiments, insulative segments comprising the material of the upper insulative grid structure (see 112 of FIG. 1B) do not extend in a grid pattern. Instead, insulative segments (e.g., the second insulative segment 124 and a seventh insulative segment 302) extend directly over portions of the lower insulative grid structure 110 corresponding to a focal points of the plurality of microlenses and intersections of the lower insulative grid structure that are beneath a central portion of the plurality of microlenses. For example, the second insulative segment 124 and a first portion 128a of the upper insulative layer 128 cover a portion of the lower insulative grid structure 110 directly beneath a central portion 304 of the first microlens 120, while the seventh insulative segment 302 comprising a same material as the second insulative segment and a second portion 128b of the upper insulative layer 128 cover a portion of the lower insulative grid structure 110 beneath a central portion 306 of the second microlens 210.

The insulative segments comprising a high-n material (e.g., a same material as the upper insulative grid structure (see 112 of FIG. 1B)) beneath the first microlens 120 are separated from the insulative segments comprising a high-n material (e.g., a same material as the upper insulative grid structure (see 112 of FIG. 1B)) beneath the second microlens 210 by the lower insulative grid structure 110 (see FIG. 3B). Portions of the upper insulative layer 128 (e.g., the first portion 128a) beneath the first microlens 120 are separated from the portions of the upper insulative layer 128 (e.g., the second portion 128b) beneath the second microlens by the overlying insulative layer 206. The selective placement of the high-n material at the focal point of the microlenses results in insulative segments surrounding the photodetectors corresponding to a microlens to be undisturbed by the process of forming the high-n material, resulting in further flexibility in the forming of the DTI structure 108. Further, the embodiments represented by FIGS. 3A and 3B preserve the optical properties of the materials chosen for the DTI structure 108 surrounding the photodetectors corresponding to the first microlens 120 as well as the optical properties of the overlying insulative layer 206 outside of the central portion 304 of the first microlens 120.

As shown in the top down view 300b of FIG. 3B, in some embodiments, the first segment 122 has a first length 308 and is confined between fifth insulative segment 212 and the sixth insulative segment 214 of the lower insulative grid structure 110. In further embodiments, the second segment 124 has a second length 310 and is confined between inner sidewalls of the first insulative segment 122, where the second length 310 is less than the first length 308. In some embodiments, insulative segments comprising a high-n material are directly above every odd numbered intersection of the DTI structure (see 108 of FIG. 3B) in a first direction 312 and in a second direction 314 perpendicular to the first direction. In some embodiments, the first insulative segment 122 is bisected by a perpendicular insulative segment 316 extending in the second direction 314.

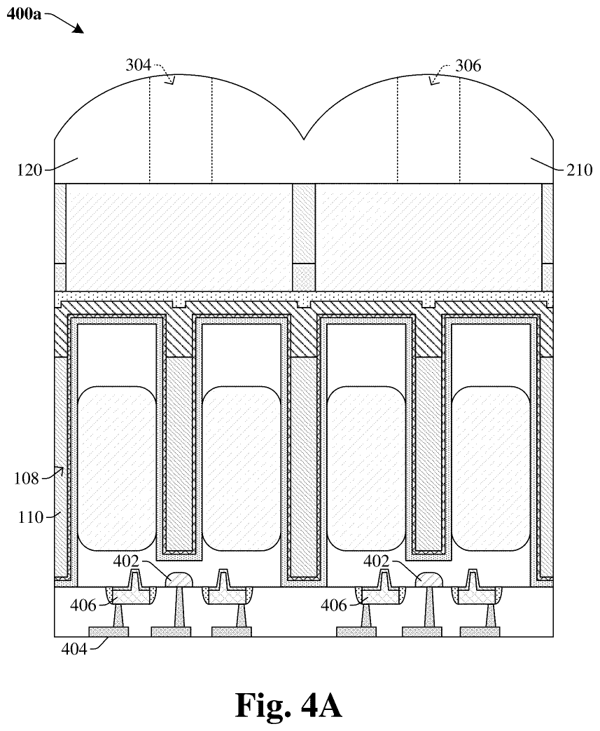

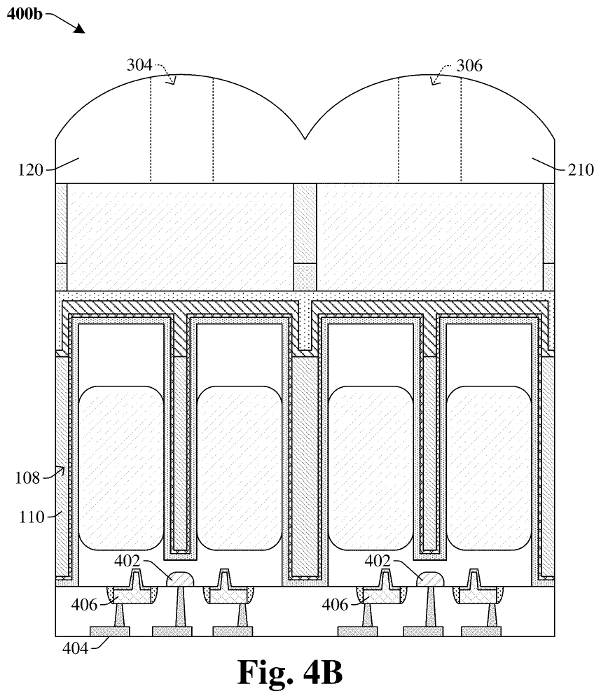

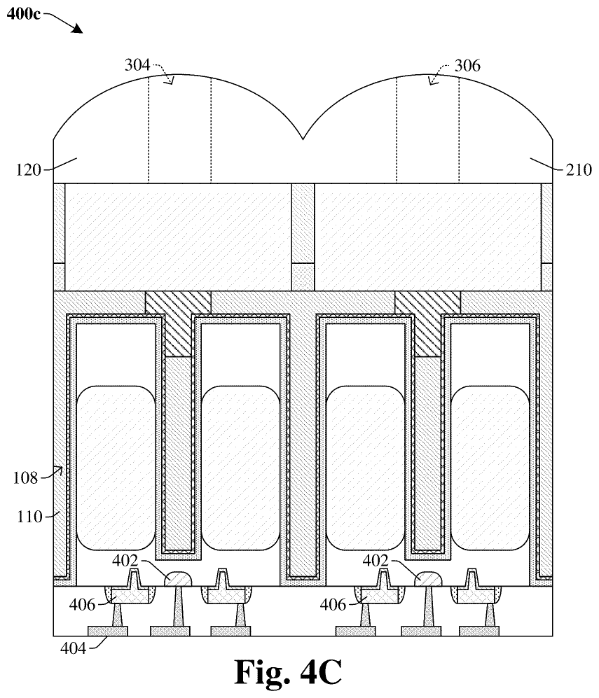

FIGS. 4A, 4B, and 4C illustrate cross-sectional views 400a, 400b, 400c of an image sensor comprising floating diffusion regions shared between multiple transfer transistors. FIGS. 4A, 4B, and 4C are described concurrently. FIGS. 4A, 4B, and 4C illustrate DTI structures 108 with the features shown in FIGS. 1A, 2A, and 3A, wherein portions of the lower insulative grid structures 110 directly beneath central portions 304, 306 of the first and second microlenses 120, 210 directly overly portions of the substrate 106 and floating diffusion regions 402. The floating diffusion regions 402 are coupled to circuitry of the image sensor, such as the pixel circuitry and image signal processor (ISP) circuitry. The floating diffusion regions 402 are coupled to an interconnect structure 404. The interconnect structure 404 further is coupled to a plurality of transfer transistors 406. The plurality of transfer transistors 406 are configured to form conductive channels between the photodetector array and the floating diffusion region 402, such that charge from the photodetector array is transferred to the pixel circuitry.

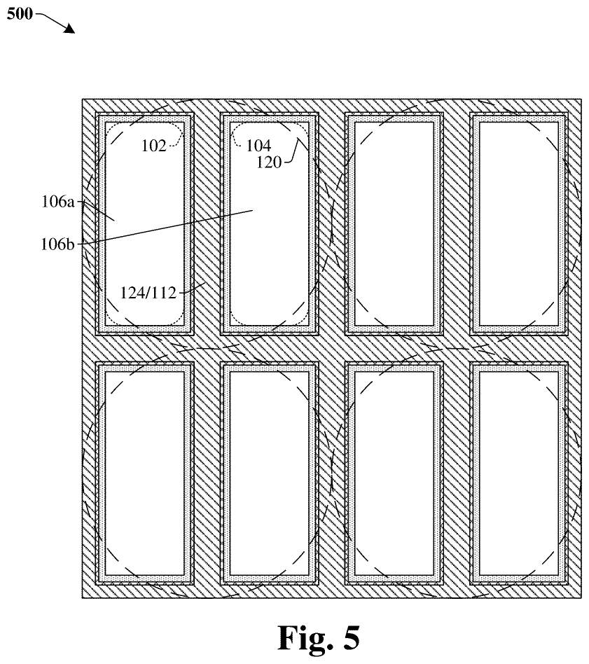

FIG. 5 illustrates a top down view 500 of an image sensor with two photodetector regions beneath one microlens. As shown in the top down view in FIG. 5, in some embodiments there are two substrate regions 106a, 106b directly beneath the first microlens 120 (shown in phantom) containing the first photodetector 102 and the second photodetector 104, respectively. The second insulative segment 124 of the upper insulative grid structure 112 is not bisected by an additional segment directly beneath the first microlens 120. In other embodiments (see FIGS. 1B, 2B, and 3B), there are the four substrate regions 130 isolated from one another by the DTI structure 108 and directly beneath the first microlens 120, where the four substrate regions 130 are isolated by the first insulative segment (see 122 of FIG. 1A), the second insulative segment 124, and the perpendicular insulative segment (see 316 of FIG. 3B) intersecting the first insulative segment (see 122 of FIG. 1A) and the second insulative segment 124 at a midpoint between the four substrate regions 130.

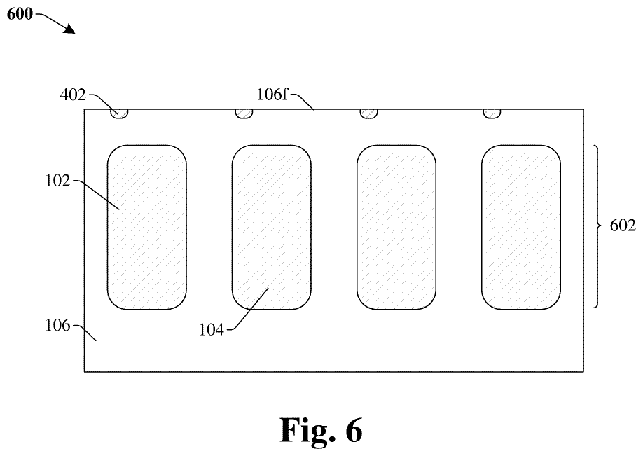

FIGS. 6-14 illustrate a series of cross-sectional views 600-1400 of some embodiments of a method of forming an image sensor with a dual material fill to reduce cross-talk. Although FIGS. 6-14 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in the cross-sectional view 600 of FIG. 6, a plurality of photodetectors 602 comprising the first photodetector 102 and the second photodetector 104 are formed within the substrate 106. In some embodiments, the plurality of photodetectors 602 are or comprise n-type regions of the substrate that are formed using an implantation process. Further, the floating diffusion regions are formed on a first side 106f of the substrate 106. In some embodiments, the floating diffusion regions 402 are or comprise n-type regions (e.g., substrate regions with n-type doping) that are formed using an implantation process. The substrate has a first refractive index.

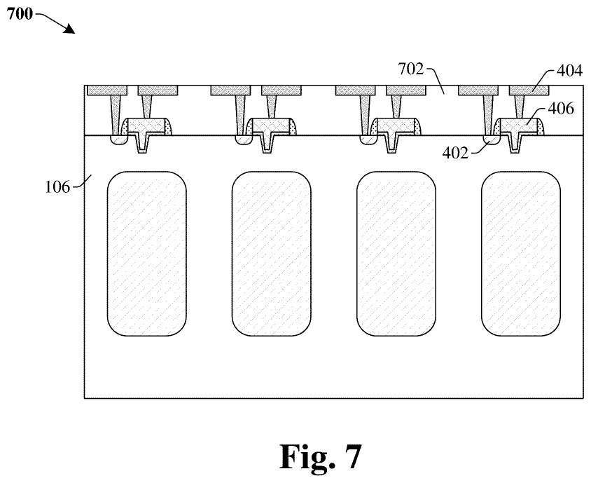

As shown in the cross-sectional view 700 of FIG. 7, the transfer transistors 406 and the interconnect structure 404 is formed over the substrate 106. The interconnect structure 404 comprises one or more wire levels and one or more via levels forming conductive paths over the substrate 106 and coupled to the transfer transistors 406 and the floating diffusion regions 402. Further, a plurality of interlayer dielectric layers 702 are formed between forming wire levels and via levels of the interconnect structure 404. The transfer transistors 406 are configured to independently induce a channel between a photodetector of the plurality of photodetectors 602 and a floating diffusion region of the floating diffusion regions 402 when a threshold voltage at a transistor gate is met. In some embodiments, the interconnect structure 404 comprises a conductive material, such as copper, aluminum, tungsten, a conductive metal alloy, or the like. In some embodiments, the plurality of interlayer dielectric layers 702 are or comprise an insulative material, such as silicon dioxide (SiO₂), silicon nitride (Si₃N₄), or the like. The interconnect structure 404 and the transfer transistors 406 are formed using one or more deposition processes (e.g., physical vapor deposition (PVD), atomic layer deposition (ALD), chemical vapor deposition (CVD), or the like) and removal processes (e.g., dry etching, self-aligned etching, planarization processes, or the like). In some embodiments, the interconnect structure is formed using a damascene process, a dual damascene process, or the like.

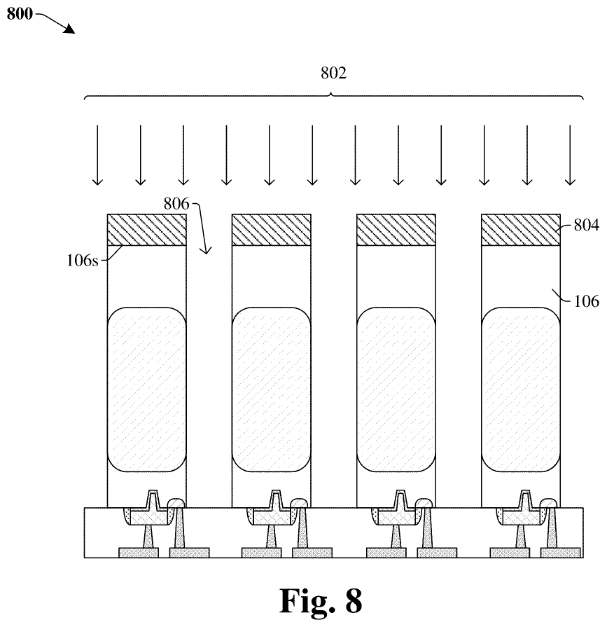

As shown in the cross-sectional view 800 of FIG. 8, in some embodiments, a first masking layer 804 is formed over a second side 106s of the substrate 106. In some embodiments, the first masking layer 804 is formed using a deposition process, a spin on process, a dipping process, or the like. The first masking layer 804 is then patterned. In some embodiments, the first masking layer 804 is a photoresist and is patterned using photolithography. Openings in the first masking layer correspond to the position of the DTI structure (see 108 of FIG. 1A) to be formed hereafter.

After the first masking layer 804 is patterned, a first etching process 802 is performed. In some embodiments, the first etching process 802 is an anisotropic dry etching process. The first etching process results in a first plurality of openings 806 corresponding to the position of the DTI structure (see 108 of FIG. 1A).

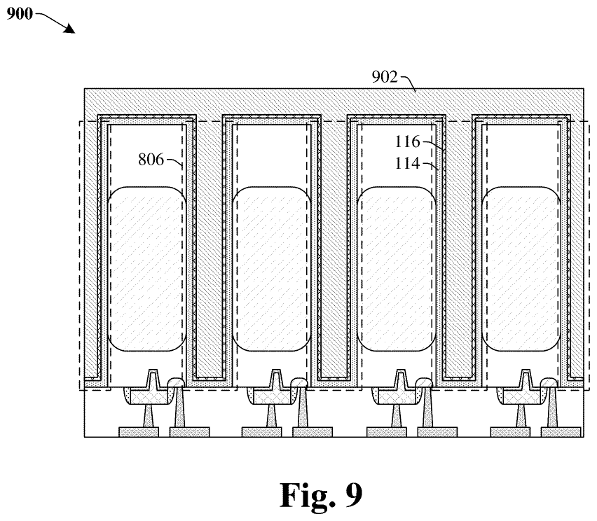

As shown in the cross-sectional view 900 of FIG. 9, the antireflective coating 114, the etch stop layer 116, and a first conformal insulative layer 902 are formed in the first plurality of openings 806 (shown in phantom). In some embodiments, the antireflective coating 114 is or comprises one or more of silicon dioxide (SiO₂), tantalum pentoxide (Ta₂O₅), titanium oxide (TiO₂), silicon nitride (Si₃N₄), or the like. In some embodiments, the etch stop layer is or comprises one or more of silicon nitride (Si₃N₄) or the like. In some embodiments, the first conformal insulative layer 902 is or comprises an insulative material, such as silicon dioxide (SiO₂) or the like. The material of the first conformal insulative layer 902 has a second refractive index that is less than the first refractive index of the substrate 106. The antireflective coating 114, the etch stop layer 116, and the first conformal insulative layer 902 are independently formed using one or more of PVD, ALD, CVD, or the like.

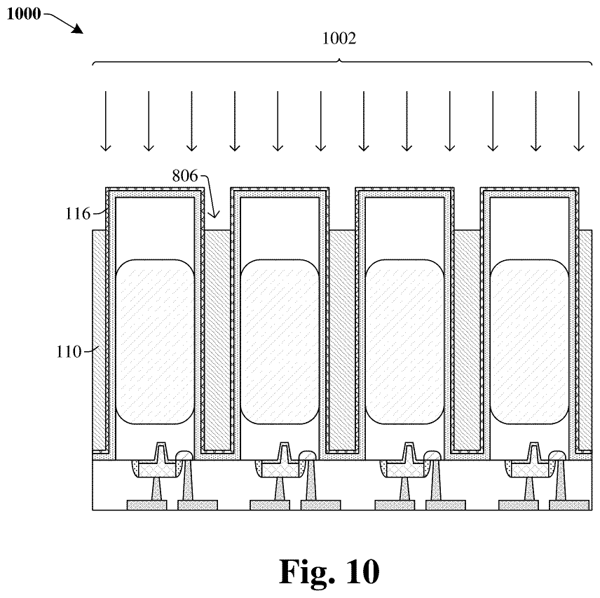

As shown in the cross-sectional view 1000 of FIG. 10, a portion of the first conformal insulative layer (see 902 of FIG. 9) is removed, resulting in the lower insulative grid structure 110 remaining within the first plurality of openings 806. An upper portion of the first plurality of openings 806 and inner sidewalls of the etch stop layer 116 are exposed. In some embodiments, the portion of the first conformal insulative layer (see 902 of FIG. 9) is removed using an etching process 1002, such as a self-aligned dry etching process or the like.

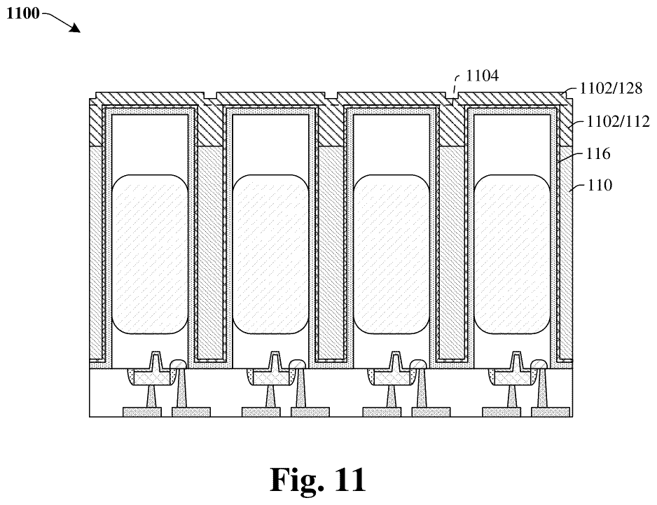

As shown in the cross-sectional view 1100 of FIG. 11, a second conformal insulative layer 1102 is formed over the substrate 106, comprising the upper insulative grid structure 112 and the upper insulative layer 128. The second conformal insulative layer 1102 is or comprises an insulative material with a third refractive index greater than the second refractive index of the lower insulative grid structure 110, such as silicon nitride (Si₃N₄), hafnium oxide (HfO₂), tantalum oxide (HfO₂), titanium oxide (TiO₂), or the like. In further embodiments, the second conformal insulative layer 1102 is or comprises a transparent insulative material configured to result in light passing through the upper insulative layer 128 to the substrate 106. The upper insulative grid structure 112 is defined as portions of the second conformal insulative layer 1102 directly between inner sidewalls of the etch stop layer 116. The upper insulative layer 128 is defined as the portion of the second conformal insulative layer 1102 overlying inner sidewalls of the etch stop layer 116. An interface 1104 between the upper insulative grid structure 112 and the upper insulative layer 128 extends level with the uppermost surface of the etch stop layer 116. In some embodiments, the second conformal insulative layer 1102 is formed using a deposition process such as one or more of PVD, ALD, CVD, or the like.

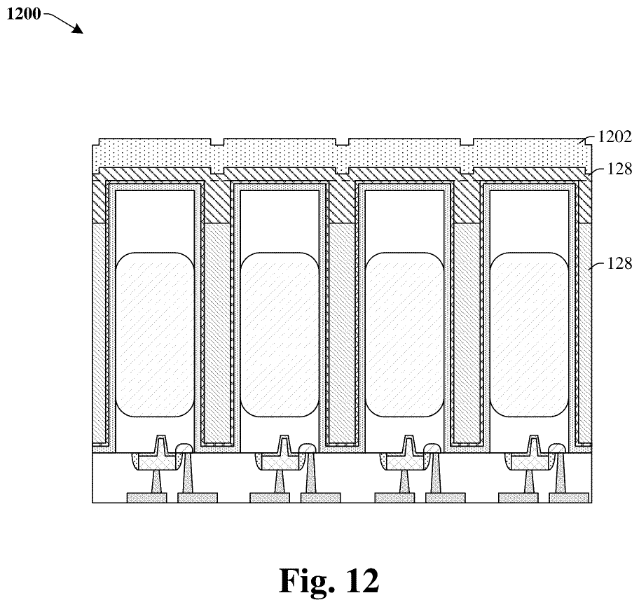

As shown in the cross-sectional view 1200 of FIG. 12, a third conformal insulative layer 1202 is formed on the upper insulative layer 128. The third conformal insulative layer 1202 is or comprises an insulative material such as silicon dioxide (SiO₂) or the like. In some embodiments, the second conformal insulative layer 1102 is formed using a deposition process such as one or more of PVD, ALD, CVD, or the like.

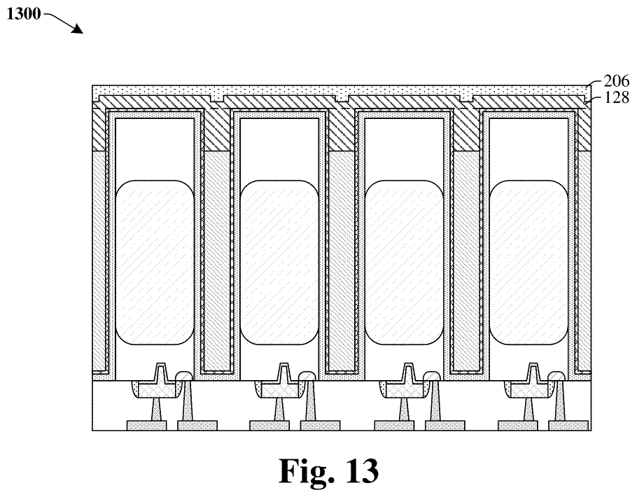

As shown in the cross-sectional view 1300 of FIG. 13, a portion of the third conformal insulative layer (see 1202 of FIG. 12) is removed, resulting in the overlying insulative layer 206 covering the upper insulative layer 128. In some embodiments, the portion of the third conformal insulative layer (see 1202 of FIG. 12) is removed using a planarization process (e.g., a chemical mechanical planarization (CMP) process). The overlying insulative layer 206 has a substantially planar upper surface.

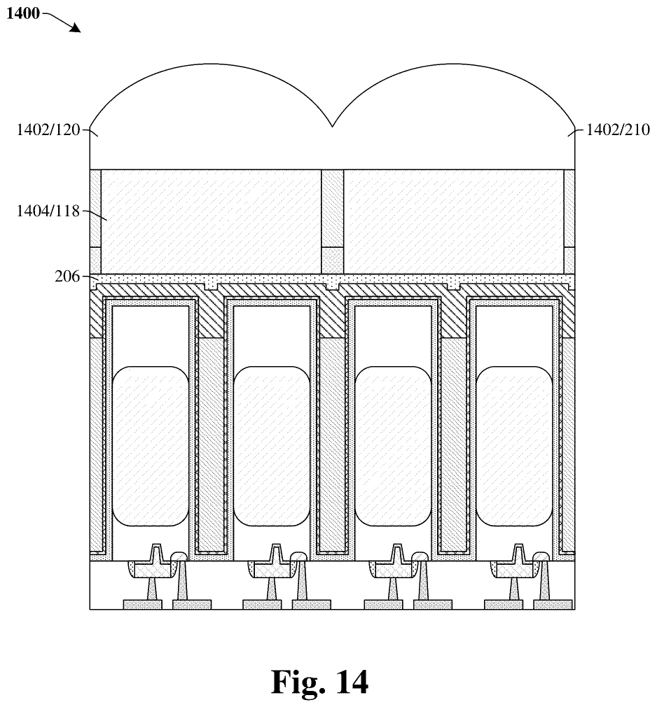

As shown in the cross-sectional view 1400 of FIG. 14, a plurality of color filters 1404 comprising the color filter 118 and a plurality of microlenses 1402 comprising the first microlens 120 and the second microlens 210 are formed on the upper surface of the overlying insulative layer 206. In some embodiments, the plurality of color filters 1404 are formed such that the colors filters independently overly two different photodetectors (e.g., the color filter 118 extends directly over the first photodetector 102 and the second photodetector 104, but not the third photodetector (see 132 of FIG. 1B) and the fourth photodetector (see 134 of FIG. 1B), as shown in FIG. 5). In other embodiments, the plurality of color filters 1404 are formed such that the colors filters independently overly four different photodetectors (e.g., the color filter 118 extends directly over the first photodetector 102, the second photodetector 104, the third photodetector (see 132 of FIG. 1B), and the fourth photodetector (see 134 of FIG. 1B), as shown in FIGS. 1B, 2B, and 3B). In some embodiments, the plurality of microlenses 1402 are positioned such that the microlenses are individually centered on the color filters of the plurality of color filters 1404. In other embodiments, the plurality of microlenses 1402 are offset from the centers of the color filters based on their position on the photodetector array. That is, microlenses near a central portion of the photodetector array may be centered on the color filters directly beneath them, while microlenses near the edges of the photodetector array may be offset from the center of the color filters to more effectively capture the incident light that is approaching at an oblique angle.

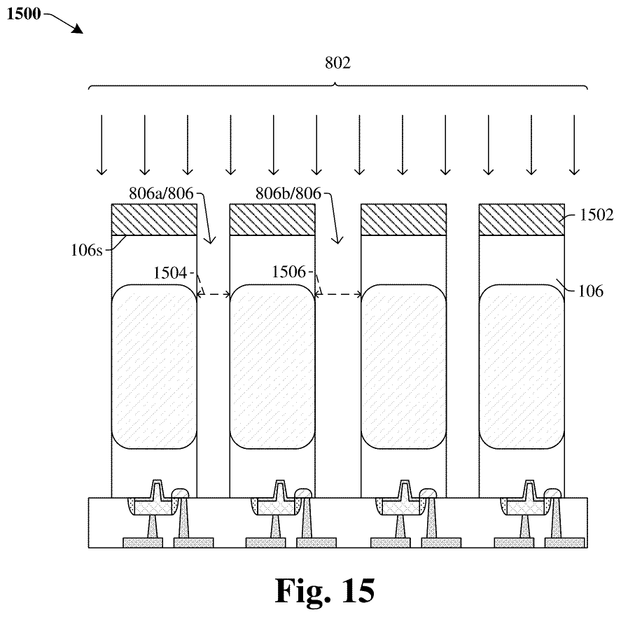

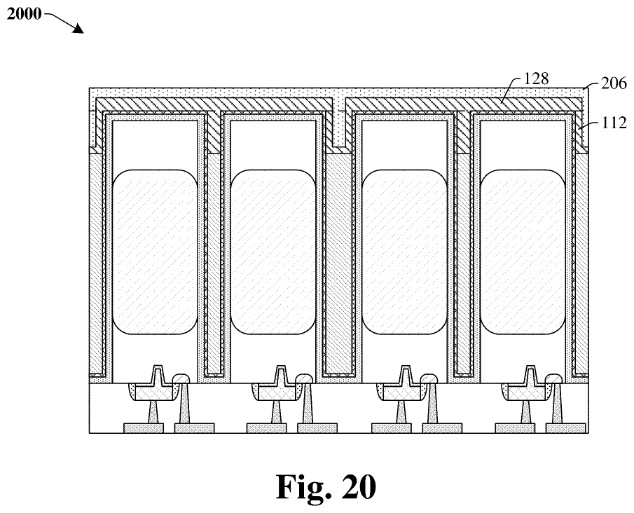

FIGS. 15-20 illustrate a series of cross-sectional views 1500-2000 of some embodiments of a method of forming a DTI structure with a dual material fill where DTI segments extending between first and second photodetectors are separated by a first insulative segment that is thinner than a second insulative segment to one side of the first and second photodetector regions. Although FIGS. 15-20 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. The method shown in FIGS. 15-20 is performed after following the steps described in relation to FIGS. 6 and 7 as an alternative to the steps described in relation to FIGS. 8-13. The method continues following the steps described in relation to FIG. 14 after the steps corresponding to FIG. 20 are performed.

As shown in the cross-sectional view 1500 of FIG. 15, in some embodiments, a second masking layer 1502 is formed over a second side 106s of the substrate 106. In some embodiments, the second masking layer 1502 is formed using a deposition process, a spin on process, a dipping process, or the like. The second masking layer 1502 is then patterned. In some embodiments, the second masking layer 1502 is a photoresist and is patterned using photolithography. Openings in the first masking layer correspond to the position of the DTI structure (see 108 of FIG. 2A) to be formed hereafter.

After the second masking layer 1502 is patterned, a first etching process 802 is performed. In some embodiments, the first etching process 802 is an anisotropic dry etching process. The first etching process results in a first plurality of openings 806 corresponding to the position of the DTI structure (see 108 of FIG. 2A). A first portion 806a of the first plurality of openings 806 have a first width 1504 and a second portion 806b of the first plurality of openings 806 have a second width 1506 greater than the first width 1504. The first width 1504 corresponds to the position of insulative segments extending between photodetectors directly under the same color filter (e.g., the first insulative segment (see 122 of FIG. 2A) and the second insulative segment (see 124 of FIG. 2A)) and the second width 1506 corresponds to the position of insulative segments extending between photodetectors beneath different color filters (e.g., the third insulative segment (see 126 of FIG. 2A) and the fourth insulative segment (see 208 of FIG. 2A)).

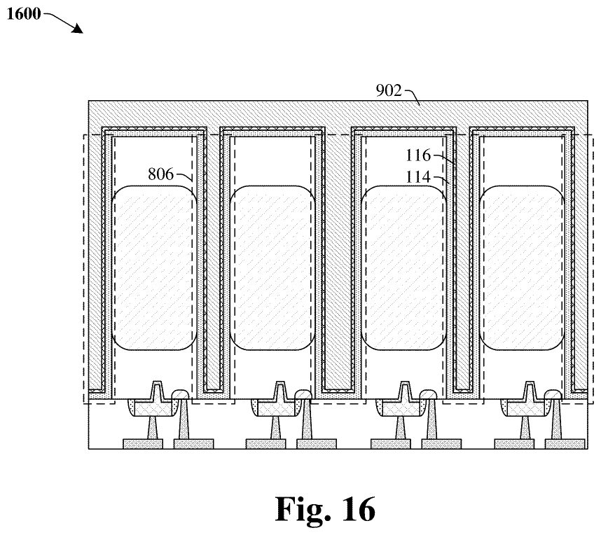

As shown in the cross-sectional view 1600 of FIG. 16, the antireflective coating 114, the etch stop layer 116, and a first conformal insulative layer 902 are formed in the first plurality of openings 806 (shown in phantom). In some embodiments, the antireflective coating 114 is or comprises one or more of silicon dioxide (SiO₂), tantalum pentoxide (Ta₂O₅), titanium oxide (TiO₂), silicon nitride (Si₃N₄), or the like. In some embodiments, the etch stop layer is or comprises one or more of silicon nitride (Si₃N₄) or the like. In some embodiments, the first conformal insulative layer 902 is or comprises an insulative material, such as silicon dioxide (SiO₂) or the like. The material of the first conformal insulative layer 902 has a second refractive index that is less than the first refractive index of the substrate 106. The antireflective coating 114, the etch stop layer 116, and the first conformal insulative layer 902 are independently formed using one or more of PVD, ALD, CVD, or the like.

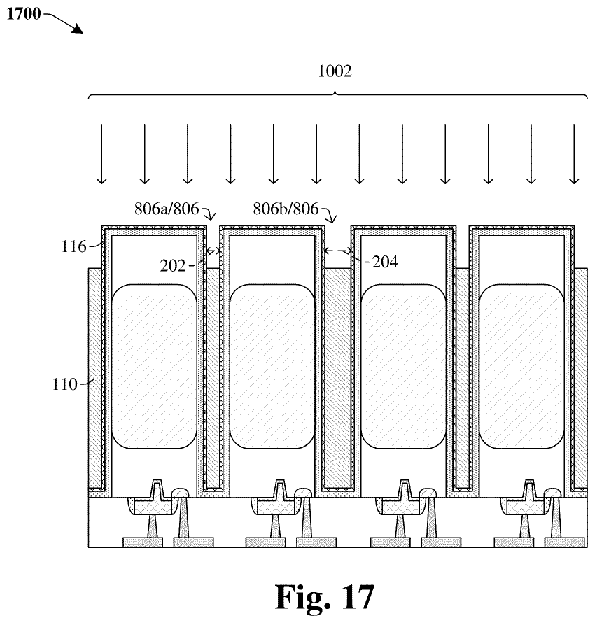

As shown in the cross-sectional view 1700 of FIG. 17, a portion of the first conformal insulative layer (see 902 of FIG. 9) is removed, resulting in the lower insulative grid structure 110 remaining within the first plurality of openings 806. An upper portion of the first plurality of openings 806 and inner sidewalls of the etch stop layer 116 are exposed. In some embodiments, the portion of the first conformal insulative layer (see 902 of FIG. 9) is removed using an etching process 1002, such as a self-aligned dry etching process or the like. After the etching process 1002, the exposed portions of the first portion 806a of the first plurality of openings 806 have a width equal to first thickness 202, and the exposed portions of the second portion 806b of the first plurality of openings 806 have a width equal to the second thickness 204.

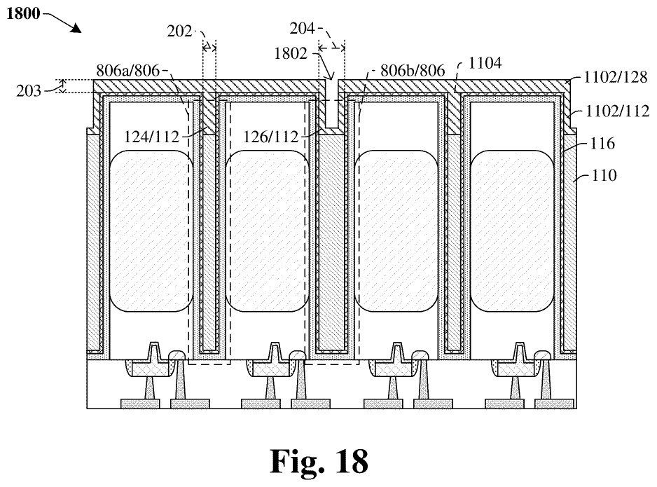

As shown in the cross-sectional view 1800 of FIG. 18, a second conformal insulative layer 1102 is formed over the substrate 106, comprising the upper insulative grid structure 112 and the upper insulative layer 128. The second conformal insulative layer 1102 is or comprises an insulative material with a third refractive index greater than the second refractive index of the lower insulative grid structure 110, such as silicon nitride (Si₃N₄), hafnium oxide (HfO₂), tantalum oxide (HfO₂), titanium oxide (TiO₂), or the like. In further embodiments, the second conformal insulative layer 1102 is or comprises a transparent insulative material configured to result in light passing through the upper insulative layer 128 to the substrate 106. The upper insulative grid structure 112 is defined as portions of the second conformal insulative layer 1102 directly between inner sidewalls of the etch stop layer 116. The upper insulative layer 128 is defined as the portion of the second conformal insulative layer 1102 overlying inner sidewalls of the etch stop layer 116. An interface 1104 between the upper insulative grid structure 112 and the upper insulative layer 128 extends level with the uppermost surface of the etch stop layer 116. In some embodiments, the second conformal insulative layer 1102 is formed using a deposition process such as one or more of PVD, ALD, CVD, or the like.

Insulative segments of the upper insulative grid structure 112 that are formed within the first portion 806a of the first plurality of openings 806 (e.g., the second insulative segment 124) have the first thickness 202. Insulative segments of the upper insulative grid structure 112 that are formed within the second portion 806b of the first plurality of openings 806 (e.g., the third insulative segment 126) have the second thickness 204 that is greater than the first thickness 202, and further have openings 1802 that extend through the upper insulative layer 128 and into the insulative segments. The second conformal insulative layer 1102 has the height 203 equal to over double the first thickness 202.

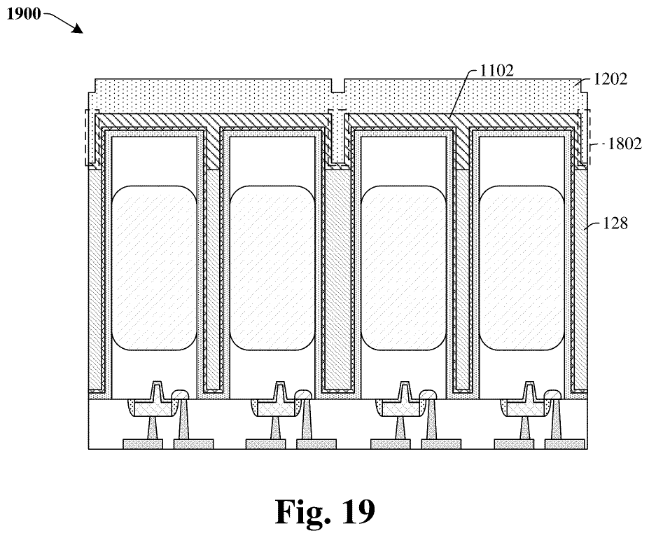

As shown in the cross-sectional view 1900 of FIG. 19, a third conformal insulative layer 1202 is formed on the second conformal insulative layer 1102. The third conformal insulative layer 1202 fills the openings 1802 that extend into the second conformal insulative layer 1102. The third conformal insulative layer 1202 is or comprises an insulative material such as silicon dioxide (SiO₂) or the like. In some embodiments, the second conformal insulative layer 1102 is formed using a deposition process such as one or more of PVD, ALD, CVD, or the like.

As shown in the cross-sectional view 2000 of FIG. 20, a portion of the third conformal insulative layer (see 1202 of FIG. 19) is removed, resulting in the overlying insulative layer 206 covering the upper insulative layer 128 and extending into the upper insulative grid structure 112. In some embodiments, the portion of the third conformal insulative layer (see 1202 of FIG. 19) is removed using a planarization process (e.g., a CMP process, or the like). The overlying insulative layer 206 has a substantially planar upper surface. The method continues following the steps corresponding to FIG. 14.

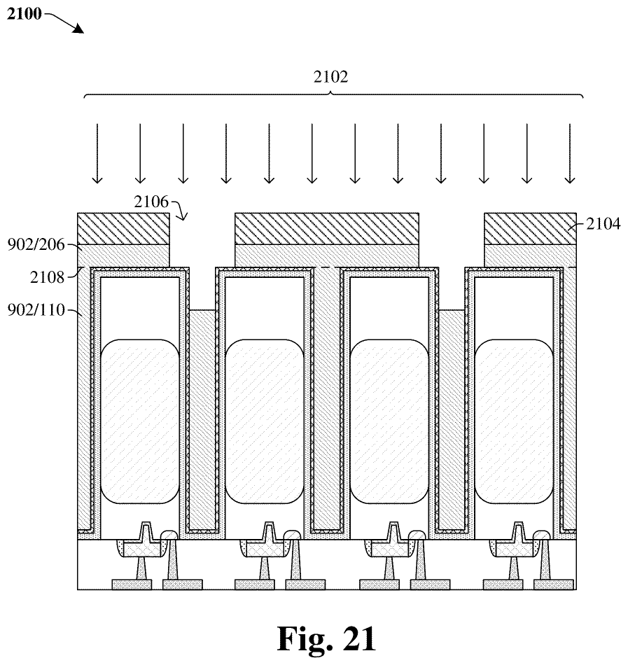

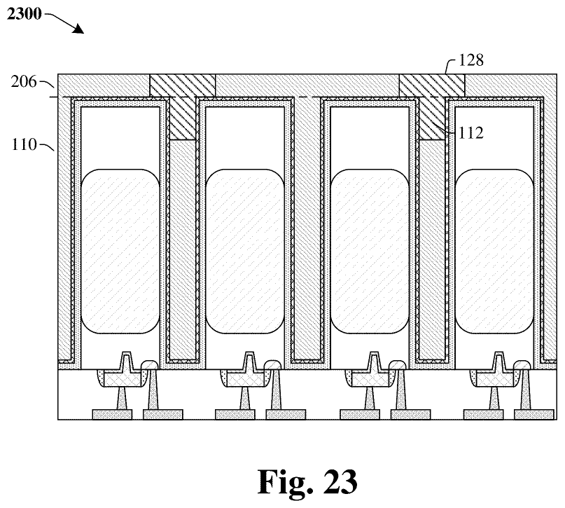

FIGS. 21-23 illustrate a series of cross-sectional views 2100-2300 of some embodiments of a method of forming a DTI structure with a dual material fill where an overlying insulative layer separates portions of the DTI segments comprising a material with a higher refractive index than the overlying insulative layer. Although FIGS. 21-23 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. The method shown in FIGS. 21-23 is performed after following the steps described in relation to FIGS. 6-9 as an alternative to the steps described in relation to FIGS. 10-13, and continues following the steps described in relation to FIG. 14 after the steps corresponding to FIG. 23 are performed.

As shown in the cross-sectional view 2100 of FIG. 21, in some embodiments, a third masking layer 2104 is formed over the first conformal insulative layer 902. In some embodiments, the third masking layer 2104 is formed using a deposition process, a spin on process, a dipping process, or the like. The third masking layer 2104 is then patterned. In some embodiments, the third masking layer 2104 is a photoresist and is patterned using photolithography. Openings in the third masking layer 2104 correspond to the position of the upper insulative layer (see 128 of FIG. 3A) and upper insulative segments to be formed hereafter.

After the third masking layer 2104 is patterned, a third etching process 2102 is performed. In some embodiments, the third etching process 2102 is an anisotropic dry etching process. The third etching process 2102 results in a second plurality of openings 2106 corresponding to the positions of the upper insulative layer (see 128 of FIG. 3A) and upper insulative segments to be formed hereafter.

After the third etching process 2102, portions of the first conformal insulative layer 902 comprising overlying insulative layer 206 and the lower insulative grid structure 110 remain on the substrate 106. The lower insulative grid structure 110 is defined as portions of the first conformal insulative layer 902 directly between inner sidewalls of the etch stop layer 116. The overlying insulative layer 206 is defined as the portion of the first conformal insulative layer 902 overlying inner sidewalls of the etch stop layer 116. An interface 2108 between the lower insulative grid structure 110 and the overlying insulative layer 206 extends level with the uppermost surface of the etch stop layer 116.

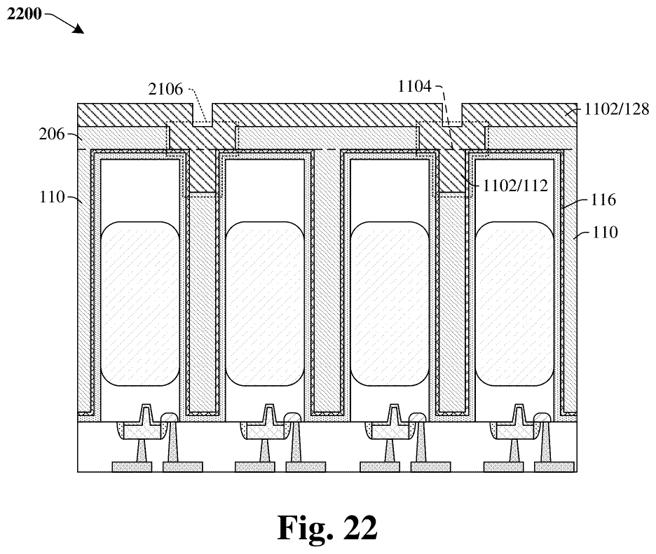

As shown in the cross-sectional view 2200 of FIG. 22, a second conformal insulative layer 1102 is formed on an upper surface of the overlying insulative layer 206 and in the second plurality of openings 2106, comprising the upper insulative grid structure 112 and the upper insulative layer 128. The second conformal insulative layer 1102 is or comprises an insulative material with a third refractive index greater than the second refractive index of the lower insulative grid structure 110, such as silicon nitride (Si₃N₄), hafnium oxide (HfO₂), tantalum oxide (HfO₂), titanium oxide (TiO₂), or the like. The upper insulative grid structure 112 is defined as portions of the second conformal insulative layer 1102 directly between inner sidewalls of the etch stop layer 116. The upper insulative layer 128 is defined as the portion of the second conformal insulative layer 1102 overlying inner sidewalls of the etch stop layer 116. An interface 1104 between the upper insulative grid structure 112 and the upper insulative layer 128 extends level with the uppermost surface of the etch stop layer 116. In some embodiments, the second conformal insulative layer 1102 is formed using a deposition process such as one or more of PVD, ALD, CVD, or the like.

As shown in the cross-sectional view 2300 of FIG. 23, a portion of the second conformal insulative layer (see 1102 of FIG. 22) is removed, resulting in the overlying insulative layer 206 surrounding and separating portions of the upper insulative layer 128. In some embodiments, the portion of the second conformal insulative layer (see 1102 of FIG. 22) is removed using a planarization process (e.g., a CMP process, or the like). After the planarization process, the overlying insulative layer 206 and the upper insulator have a substantially planar upper surface. The method continues following the steps corresponding to FIG. 14.

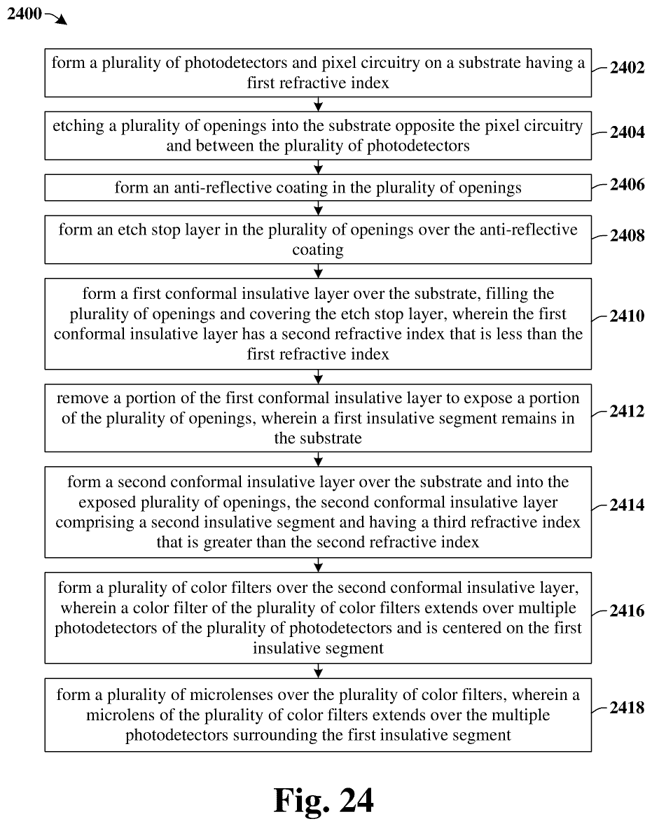

FIG. 24 illustrates a flowchart 2400 of some embodiments of a method of forming an image sensor with a dual material fill to reduce cross-talk. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At 2402, a plurality of photodetectors and pixel circuitry are formed on a substrate having a first refractive index. An example of a drawing illustrating this step can be found, for example, in FIGS. 6-7.

At 2404, a plurality of openings are etched into the substrate opposite the pixel circuitry and between the plurality of photodetectors. An example of a drawing illustrating this step can be found, for example, in FIG. 8.

At 2406, an anti-reflective coating is formed in the plurality of openings. An example of a drawing illustrating this step can be found, for example, in FIG. 9.

At 2408, an etch stop layer is formed in the plurality of openings over the anti-reflective coating. An example of a drawing illustrating this step can be found, for example, in FIG. 9.

At 2410, a first conformal insulative layer is formed over the substrate, filling the plurality of openings and covering the etch stop layer, wherein the first conformal insulative layer has a second refractive index that is less than the first refractive index. An example of a drawing illustrating this step can be found, for example, in FIG. 9.

At 2412, a portion of the first conformal insulative layer is removed to expose a portion of the plurality of openings, wherein a first insulative segment remains in the substrate. An example of a drawing illustrating this step can be found, for example, in FIG. 10.

At 2414, a second conformal insulative layer is formed over the substrate and in the exposed portion of the plurality of openings, the second conformal insulative layer comprising a second insulative segment and having a third refractive index that is greater than the second refractive index. An example of a drawing illustrating this step can be found, for example, in FIG. 11.

At 2416, a plurality of color filters are formed over the second conformal insulative layer, wherein a color filter of the plurality of color filters extends over multiple photodetectors of the plurality of photodetectors and is centered on the first insulative segment. An example of a drawing illustrating this step can be found, for example, in FIG. 14.

At 2418, a plurality of microlenses are formed over the plurality of color filters, wherein a microlens of the plurality of color filters extends over the multiple photodetectors surrounding the first insulative segment. An example of a drawing illustrating this step can be found, for example, in FIG. 14.

Some embodiments relate to an integrated device, including: a substrate having a first refractive index, a first side, a second side, and a first and second region extending between the first side and the second side; a lower insulative grid structure within the substrate, the lower insulative grid structure having a first plurality of insulative segments arranged in a grid pattern and having a second refractive index, and extending between the first region of the substrate and the second region of the substrate; and an upper insulative grid structure overlying the lower grid structure and comprising a second plurality of insulative segments that have outer sidewalls that are substantially aligned with outer sidewalls of the first plurality of insulative segments, the second plurality of insulative segments having a third refractive index that is greater than the second refractive index and lower than the first refractive index.

Other embodiments relate to an integrated device, including: a substrate having a first refractive index, a first side, a first region, and a second region; a first insulative segment having a second refractive index and extending between the first region and the second region spaced from the first side of the substrate, where the second refractive index is less than the first refractive index; a second insulative segment having a third refractive index and extending from the first side of the substrate to the first insulative segment within the substrate, where the third refractive index is greater than the second refractive index.

Yet other embodiments relate to a method of forming an integrated device, including: etching a plurality of openings into a substrate having a first refractive index; forming an anti-reflective coating in the plurality of openings; forming an etch stop layer in the plurality of openings over the anti-reflective coating; forming a first conformal insulative layer over the substrate, filling the plurality of openings and covering the etch stop layer, wherein the first conformal insulative layer has a second refractive index that is less than the first refractive index; removing a portion of the first conformal insulative layer to expose a portion of the plurality of openings, wherein a first insulative segment remains in the substrate; and forming a second conformal insulative layer over the substrate and into the exposed portion of the plurality of openings, the second conformal insulative layer comprising a second insulative segment and having a third refractive index that is greater than the second refractive index.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated device, comprising:
a substrate having a first refractive index, a first side, a second side, and a first and second region extending between the first side and the second side;
a first photodetector within the first region of the substrate and a second photodetector within the second region of the substrate;
a lower insulative grid structure within the substrate, the lower insulative grid structure comprising a first plurality of insulative segments arranged in a grid pattern and having a second refractive index, the first plurality of insulative segments extending between the first region of the substrate and the second region of the substrate and isolating the first photodetector from the second photodetector; and
an upper insulative grid structure overlying the lower insulative grid structure and comprising a second plurality of insulative segments that have outer sidewalls that are substantially aligned with outer sidewalls of the first plurality of insulative segments, the second plurality of insulative segments having a third refractive index that is greater than the second refractive index and lower than the first refractive index.

2. The integrated device of claim 1, further comprising:
a microlens directly overlying the first region and the second region of the substrate; and
a color filter directly overlying the first region and the second region of the substrate and centered on a first insulative segment directly between the first photodetector and the second photodetector.

3. The integrated device of claim 2, further comprising:
a third region of the substrate containing a third photodetector; and
a fourth region of the substrate containing a fourth photodetector;
wherein the color filter directly overlies the third region and the fourth region and is centered on a portion of the upper insulative grid structure at a midpoint between the first photodetector, the second photodetector, the third photodetector, and the fourth photodetector.

4. The integrated device of claim 2, wherein the microlens has a focal point between the first region and the second region of the substrate and in either the upper insulative grid structure or the lower insulative grid structure.

5. The integrated device of claim 1, wherein the upper insulative grid structure further comprises an upper insulative layer that extends over the first side of the substrate from the second plurality of insulative segments.

6. The integrated device of claim 5, wherein the upper insulative layer covers the first side of the substrate.

7. The integrated device of claim 5, wherein the upper insulative layer comprises a plurality of portions that are separated by an overlying insulative layer that comprises a different material from the upper insulative layer.

8. An integrated device, comprising:
a substrate having a first refractive index, a first side, a first region, and a second region;
a first insulative segment having a second refractive index and extending between the first region and the second region spaced from the first side of the substrate, wherein the second refractive index is less than the first refractive index; and
a second insulative segment having a third refractive index and extending from the first side of the substrate to the first insulative segment within the substrate, wherein the third refractive index is greater than the second refractive index.

9. The integrated device of claim 8, wherein the third refractive index is less than the first refractive index and greater than 2, and wherein the second insulative segment is separated from the substrate by an anti-reflective coating.

10. The integrated device of claim 8, further comprising:
a plurality of external isolating segments surrounding the first region and the second region, wherein the first insulative segment has a first thickness and the plurality of external isolating segments have a second thickness greater than the first thickness.

11. The integrated device of claim 10, wherein the second insulative segment has the first thickness and consists of a first material extending from a first outer sidewall of the second insulative segment to a second outer sidewall of the second insulative segment, and
wherein the plurality of external isolating segments comprise a third insulative segment with the first material surrounding an insulative core comprising a second material different from the first material.

12. The integrated device of claim 8, wherein the first insulative segment has a first length extending in a first direction from a third insulative segment to a fourth insulative segment, the third insulative segment and the fourth insulative segment extending in a second direction perpendicular to first direction; and
wherein the second insulative segment overlies a central portion of the first insulative segment and has a second length that is less than the first length.

13. The integrated device of claim 8, further comprising:
a first color filter overlying the first region and the second region and centered on the second insulative segment; and
a first microlens overlying the first region and the second region and centered on the second insulative segment.

14. A method of forming an integrated device, comprising:
etching a plurality of openings into a substrate having a first refractive index;
forming an anti-reflective coating in the plurality of openings;
forming an etch stop layer in the plurality of openings over the anti-reflective coating;
forming a first conformal insulative layer over the substrate, filling the plurality of openings and covering the etch stop layer, wherein the first conformal insulative layer has a second refractive index that is less than the first refractive index;
removing a portion of the first conformal insulative layer to expose a portion of the plurality of openings, wherein a first insulative segment remains in the substrate; and
forming a second conformal insulative layer over the substrate and into the exposed portion of the plurality of openings, the second conformal insulative layer comprising a second insulative segment and having a third refractive index that is greater than the second refractive index.

15. The method of claim 14, further comprising:
forming a third conformal insulative layer over the second conformal insulative layer; and
removing an upper portion of the third conformal insulative layer using a planarization process.

16. The method of claim 15, wherein the third conformal insulative layer extends over a first trench holding the first insulative segment and the second insulative segment and is spaced from the first trench by the second conformal insulative layer; and
wherein the third conformal insulative layer extends into a second trench parallel to the first trench and is spaced from the substrate by the second conformal insulative layer.

17. The method of claim 15, wherein the third conformal insulative layer is spaced from the plurality of openings by the second conformal insulative layer.

18. The method of claim 14, wherein the removal of portions of the first conformal insulative layer further results in an overlying insulative layer remaining over the substrate, and further comprising:
removing a portion of the second conformal insulative layer extending above the overlying insulative layer, resulting in a first portion of an upper insulative layer remaining over the second insulative segment and comprising a same material as the second insulative segment, wherein the first portion is surrounded by the overlying insulative layer.

19. The method of claim 14, further comprising:
forming a first color filter centered on the first insulative segment and the second insulative segment, the first color filter extending from a second trench on a first side of a first trench containing the first insulative segment to a third trench on a second side opposite of the first side of the first trench.

20. The method of claim 19, further comprising:
forming a first microlens over the first color filter and having a central portion directly over an intersection between the first insulative segment and a perpendicular insulative segment bisecting the first insulative segment.
